(19) United States
(12) Patent Application Publication
(10) Pub. No.: US 2024/0347663 A1
(43) Pub. Date: Oct. 17, 2024

(54) PHOTODIODE AND PHOTOSENSITIVE DEVICE

(71) Applicant: KYOCERA Corporation, Kyoto-shi, Kyoto (JP)

(72) Inventors: Genshitaro KAWAMURA, Kirishima-shi (JP); Naoyoshi KOMATSU, Tsukuba-shi (JP); Haruhiko UDONO, Hitachi-shi (JP)

(73) Assignee: KYOCERA Corporation, Kyoto-shi, Kyoto (JP)

(21) Appl. No.: 18/292,137

(22) PCT Filed: Jul. 25, 2022
(86) PCT No.: PCT/JP2022/028630

§ 371 Date: Jan. 25, 2024

(30) Foreign Application Priority Data
Jul. 29, 2021 (JP) 2021-124253
Jul. 30, 2021 (JP) 2021-125158

(51) Int. Cl. H01L 31/105; H01L 31/0216; H01L 31/0224; H01L 31/0232; H01L 31/032; H01L 31/0352

(52) U.S. Cl. CPC H01L 31/105; H01L 31/02161; H01L 31/022408; H01L 31/02327; H01L 31/032; H01L 31/035281

(57) ABSTRACT

A photodiode includes: a p+ type semiconductor layer having a first surface in contact with a first electrode and a surface protective film located at a peripheral portion of the first electrode; an n-type semiconductor layer in contact with a second surface of the p+ type semiconductor layer opposing the first surface; an n+ type semiconductor layer in contact with a third surface of the n-type semiconductor layer opposing a surface in contact with the second surface; and a second electrode in contact with a fourth surface of the n+ type semiconductor layer opposing a surface in contact with the third surface. The p+ type semiconductor layer, the n-type semiconductor layer, and the n+ type semiconductor layer contain Mg2Si.

### TECHNICAL FIELD

The present disclosure relates to a photodiode and a photosensitive device.

### BACKGROUND OF INVENTION

In Patent Document 1, a PN junction photodiode is known as a photodiode using Mg₂Si. In the PN unction photodiode, Mg₂Si is coated with Ag as a dopant impurity and heat-treated to form a local p-type layer up to a deep position with respect to an incident direction of infrared light.

### CITATION LIST

### Patent Literature

Patent Document 1: WO 2019/187222

### SUMMARY

A photodiode according to one aspect includes: a p+ type semiconductor layer including a first surface in contact with a first electrode and a surface protective film located at a peripheral portion of the first electrode; an n-type semiconductor layer in contact with a second surface of the p+ type semiconductor layer, the second surface opposing the first surface; an n+ type semiconductor layer in contact with a third surface of the n-type semiconductor layer, the third surface opposing a surface in contact with the second surface; and a second electrode in contact with a fourth surface of the n+ type semiconductor layer, the fourth surface opposing a surface in contact with the third surface, in which the p+ type semiconductor layer, the n-type semiconductor layer, and the n+ type semiconductor layer contain Mg₂Si, the fourth surface of the n+ type semiconductor layer has a first portion that is not in contact with the second electrode, and a recessed portion is provided in a third portion of the third surface of the n-type semiconductor layer, the third portion being in contact with a second portion of the n+ type semiconductor layer, the second portion being a surface opposing the first portion.

A photosensitive device according to one aspect includes the photodiode described above.

### BRIEF DESCRIPTION OF THE DRAWINGS

FIG. 1 is a cross-sectional schematic view illustrating a photodiode according to a first embodiment.

FIG. 2 is a cross-sectional schematic view illustrating a photodiode according to a second embodiment.

FIG. 3 is a cross-sectional schematic view illustrating a photodiode according to a third embodiment.

FIG. 4 is a cross-sectional schematic view illustrating a photodiode according to a fourth embodiment.

### DESCRIPTION OF EMBODIMENTS

In a PN junction photodiode such as the technology described in Patent Document 1, Ag is used as a dopant impurity. As a result, infrared light may be absorbed before reaching the PN junction, and this decreases sensitivity to received light.

Hereinafter, a photodiode and a photosensitive device according to embodiments will be described.

### First Embodiment

### Photodiode

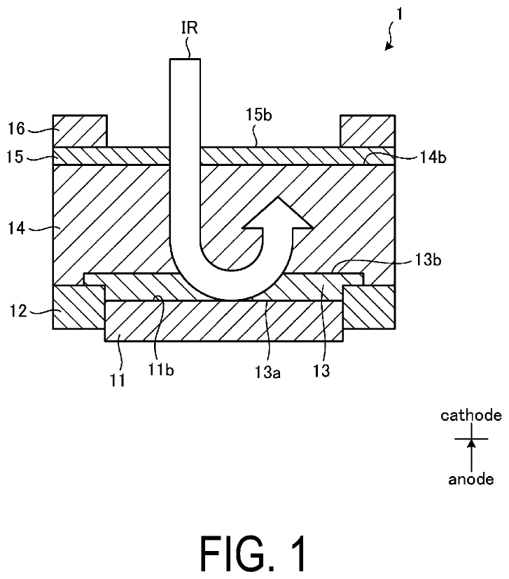

FIG. 1 is a cross-sectional schematic view illustrating a photodiode according to a first embodiment. In FIG. 1, the lower side corresponds to an anode and the upper side corresponds to a cathode. The photodiode 1 is a PIN photodiode. The photodiode 1 does not require an epitaxial layer and is based on a Mg₂Si single crystal. The photodiode 1 receives infrared light IR from the cathode side and reflects the infrared light IR.

The infrared light IR has a wavelength of 0.8 μm or more and 3.0 μm or less.

As illustrated in FIG. 1, the photodiode 1 according to the embodiment includes a first electrode 11, a surface protective film 12, a p+ type semiconductor layer 13, an n-type semiconductor layer 14, an n+ type semiconductor layer 15, and a second electrode 16.

The first electrode 11 is disposed on the anode side of the photodiode 1. The first electrode 11 contains, for example, NiAu. The first electrode 11 is disposed at a central portion of the photodiode 1. The first electrode 11 is disposed inside of the surface protective film 12. The first electrode 11 has a thickness of, for example, about 0.5 μm. In the first electrode 11, a surface in contact with a first surface 13a of the p+ type semiconductor layer 13 serves as a reflective surface 11b for the infrared light IR.

The surface protective film 12 is a protective layer for protecting a surface of the photodiode 1. The surface protective film 12 contains, for example, SiO₂ or MgO. The surface protective film 12 is disposed at a peripheral portion of the first electrode 11. The surface protective film 12 has a thickness of, for example, 0.1 μm or more and 10 μm or less.

The p+ type semiconductor layer 13 is a p+ type semiconductor layer. The p+ type semiconductor layer 13 contains Mg₂Si. The p+ type semiconductor layer 13 is doped with Ag. The p+ type semiconductor layer 13 has a thickness of, for example, 1 μm or more and 100 μm or less. The p+ type semiconductor layer 13 has the first surface 13a facing the anode side and a second surface 13b opposing the first surface 13a. The second surface 13b faces the cathode side.

The n-type semiconductor layer 14 is in contact with the second surface 13b of the p+ type semiconductor layer 13. The n-type semiconductor layer 14 is an I layer. The n-type semiconductor layer 14 is an n-type semiconductor layer. The n-type semiconductor layer 14 contains Mg₂Si. The n-type semiconductor layer 14 has a thickness of, for example, 1 μm or more and 1000 μm or less. Further, the n-type semiconductor layer 14 may have a thickness of, for example, 1 μm or more and 100 μm or less. The n-type semiconductor layer 14 has a third surface 14b opposing a surface of the p+ type semiconductor layer 13 in contact with the second surface 13b. The third surface 14b faces the cathode side.

The n+ type semiconductor layer 15 is in contact with the third surface 14b of the n-type semiconductor layer 14. The n+ type semiconductor layer 15 is an n+ type semiconductor layer. The n+ type semiconductor layer 15 contains Mg₂Si. The n+ type semiconductor layer 15 is doped with, for example, Al, boron (B), or phosphorus (P). The n+ type semiconductor layer 15 has a thickness of, for example, 0.1 μm or more and 10 μm or less. The thickness of the n+ type semiconductor layer 15 is preferably as thin as possible. The n+ type semiconductor layer 15 has a fourth surface 15b opposing a surface of the n-type semiconductor layer 14 in contact with the third surface 14b. The fourth surface 15b is an incident surface on which the infrared light IR is incident.

The second electrode 16 is in contact with the fourth surface 15b of the n+ type semiconductor layer 15. The second electrode 16 is disposed on the cathode side of the photodiode 1. The second electrode 16 contains, for example, Cr, Ti, or Au. The second electrode 16 is disposed at a peripheral portion of the photodiode 1, for example, in a ring shape. The second electrode 16 has a thickness of, for example, about 0.5 μm.

The infrared light IR is incident on the photodiode 1 configured as described above from the n-type layer opposite to the p-type layer. The infrared light IR is incident on a back surface of the photodiode 1.

### Photosensitive Device

By disposing the photodiodes 1 configured as described above in an array, the photodiode 1 can be used as a photosensitive device such as a photodetector or an imaging device.

### Action

The reflection of the infrared light IR in the photodiode 1 will be described. The infrared light IR is incident from the fourth surface 15b of the n+ type semiconductor layer 15. The infrared light IR is incident from the cathode side, in other words, from the back surface. The infrared light IR incident from the fourth surface 15b passes through the n+ type semiconductor layer 15, the n-type semiconductor layer 14, and the p+ type semiconductor layer 13 and is reflected by the reflective surface 11b of the first electrode 11. Return light of the infrared light IR reflected by the reflective surface 11b of the first electrode 11 returns to the n-type semiconductor layer 14 side.

Since the photodiode 1 is a PIN photodiode, the n-type semiconductor layer 14, which is an I layer, is depleted. Further, since the infrared light IR is incident from the back surface, the infrared light IR reaches the n-type semiconductor layer 14, which is an I layer, without passing through the p+ type semiconductor layer 13. Thereby, the infrared light IR reaches the n-type semiconductor layer 14 without being largely absorbed. Moreover, the sensitivity to received light is further improved by the return light of the infrared light IR reflected by the reflective surface 11b of the first electrode 11.

### Effects

In the present embodiment, since a PIN photodiode is used, the n-type semiconductor layer 14, which is an I layer, can be depleted. In the present embodiment, since the infrared light IR is incident from the back surface, the infrared light IR can reach the n-type semiconductor layer 14, which is an I layer, without being largely absorbed. In the present embodiment, the sensitivity to received light can be further improved by the return light of the infrared light IR reflected by the reflective surface 11b of the first electrode 11.

On the other hand, when the infrared light IR is incident from the surface as in the related art, the infrared light IR is absorbed in the p+ type semiconductor layer 13 doped with Ag before reaching the PN junction portion. As a result, the sensitivity to received light decreases.

In the present embodiment, when the thickness is to be reduced to deplete the entire n-type semiconductor layer 14, which is an I layer, the absorption can be promoted by the reflected light of the infrared light IR while keeping the thickness small.

### Second Embodiment

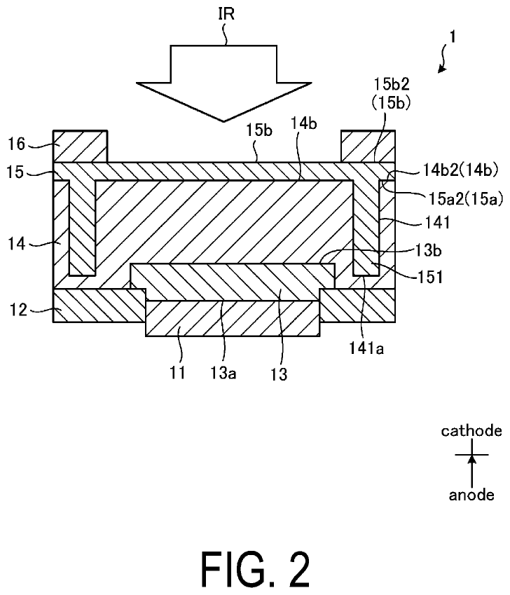

A second embodiment will be described with reference to FIG. 2. FIG. 2 is a cross-sectional schematic view illustrating a photodiode according to the second embodiment.

The fourth surface 15b of the n+ type semiconductor layer 15 has a fourth portion 15b2 in contact with the second electrode 16. A surface opposing the fourth portion 15b2 of the fourth surface 15b is a fifth portion 15a2.

The third surface 14b of the n-type semiconductor layer 14 has a sixth portion 14b2 that is in contact with the fifth portion 15a2 of the n+ type semiconductor layer 15. A non-through groove 141 is formed in the sixth portion 14b2.

The non-through groove 141 is formed on the anode side with respect to the second electrode 16. The non-through groove 141 is formed in, for example, an annular shape. A cylindrical portion 151 of the n+ type semiconductor layer 15 is located in the non-through groove 141. The cylindrical portion 151 is annularly arranged at the peripheral portion of the photodiode 1. An anode-side tip portion 141a of the non-through groove 141 is preferably located closer to the anode side than the second surface 13b of the p+ type semiconductor layer 13. The anode-side tip portion 141a of the non-through groove 141 does not reach the surface protective film 12.

In the present embodiment, the non-through groove 141 is formed in the sixth portion 14b2 of the third surface 14b of the n-type semiconductor layer 14. In the present embodiment, the non-through groove 141 is formed from the side of the fourth surface 15b, which is the incident surface for each pixel unit. In the present embodiment, a photoelectric current can be isolated because each pixel is partitioned by the groove. In the present embodiment, leakage current can be suppressed because the non-through groove 141 is provided.

With such a configuration, interference between pixels can be reduced when a photodiode array is formed using the configuration of the present embodiment. In the present embodiment, since the leakage current is suppressed, dark current between adjacent pixels can be suppressed.

### Third Embodiment

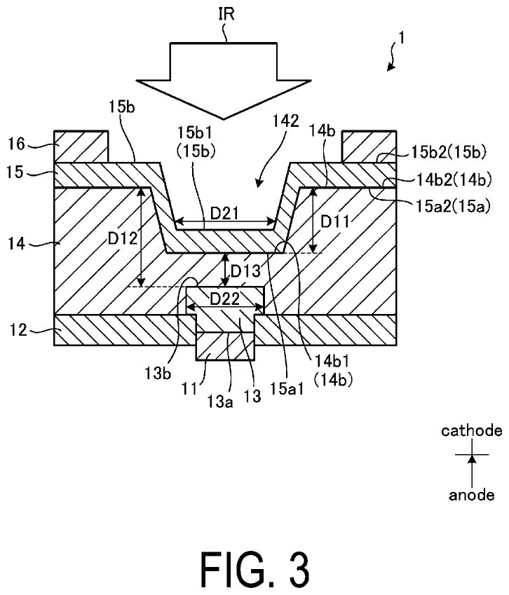

A third embodiment will be described with reference to FIG. 3. FIG. 3 is a cross-sectional schematic view illustrating a photodiode according to the third embodiment.

The fourth surface 15b of the n+ type semiconductor layer 15 has a first portion 15b1 that is not in contact with the second electrode 16. A surface of the fourth surface 15b opposing the first portion 15b1 is a second portion 15a1.

The third surface 14b of the n-type semiconductor layer 14 has a third portion 14b1 that is in contact with the second portion 15al of the n+ type semiconductor layer 15. The third portion 14b1 has a recessed portion 142. The recessed portion 142 is located inward of the sixth portion 14b2 of the third surface 14b of the n-type semiconductor layer 14, the third surface 14b being in contact with the fifth portion 15a2 of the n+ type semiconductor layer 15. A thick portion of the n-type semiconductor layer 14 remains on the outer peripheral side of the recessed portion 142.

A depth D11 of the recessed portion 142 is smaller than a depth D12 from the third surface 14b of the n-type semiconductor layer 14 to the second surface 13b of the p+ type semiconductor layer 13. The width of the recessed portion 142, that is, a width D21 of the first portion 15bl of the fourth surface 15b is preferably greater than the width of the second surface 13b of the p+ type semiconductor layer 13.

A thickness D13 of a thin portion of the n-type semiconductor layer 14 in which the recessed portion 142 is formed is smaller than the thickness of the entire n-type semiconductor layer 14.

In the present embodiment, the thickness of the n-type semiconductor layer 14 can be optimized by forming the recessed portion 142 in the n-type semiconductor layer 14. According to the present embodiment, efficient depletion can be achieved. In the present embodiment, the sensitivity to received light can be improved by suppressing absorption. The present embodiment can prevent a decrease in element intensity.

In the present embodiment, a thick portion of the n-type semiconductor layer 14 is located on the outer peripheral side of the recessed portion 142. According to the present embodiment, a decrease in the intensity of the photodiode 1 can be limited.

In the present embodiment, the width of the recessed portion 142, that is, a width D21 of the first portion 15b1 of the fourth surface 15b is greater than the width of the second surface 13b of the p+ type semiconductor layer 13. According to the present embodiment, the current extraction efficiency per unit area can be increased.

### Fourth Embodiment

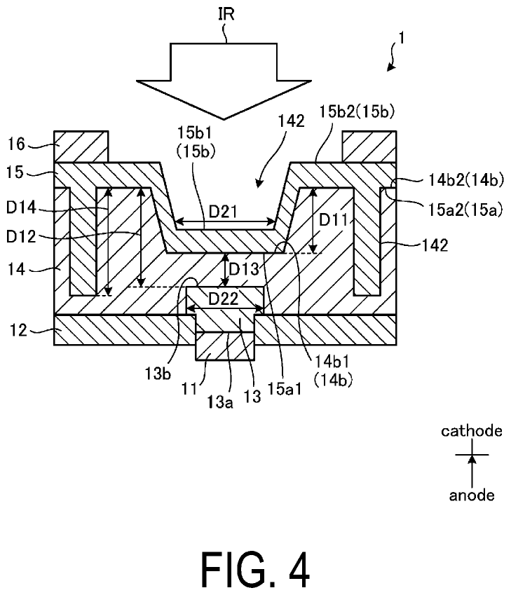

A fourth embodiment will be described with reference to FIG. 4. FIG. 4 is a cross-sectional schematic view illustrating a photodiode according to the fourth embodiment. The fourth embodiment is a combination of the second embodiment and the third embodiment.

The non-through groove 141 is formed in the sixth portion 14b2 of the third surface 14b of the n-type semiconductor layer 14. The non-through groove 141 is configured in the same manner as the second embodiment.

The recessed portion 142 is provided in the third portion 14b1 of the third surface 14b of the n-type semiconductor layer 14. The recessed portion 142 is configured in the same manner as in the third embodiment.

The depth D11 of the recessed portion 142 is preferably smaller than a depth D14 of the non-through groove 141.

In the present embodiment, the non-through groove 141 is formed in the sixth portion 14b2 of the third surface 14b of the n-type semiconductor layer 14. In the present embodiment, the non-through groove 141 is formed from the side of the fourth surface 15b, which is the incident surface for each pixel unit. In the present embodiment, a photoelectric current can be isolated because each pixel is partitioned by the groove. In the present embodiment, since the non-through groove 141 does not reach the surface protective film 12, leakage current can be suppressed.

With such a configuration, interference between pixels can be reduced when a photodiode array is formed using the configuration of the present embodiment. In the present embodiment, since the leakage current is suppressed, dark current between adjacent pixels can be suppressed.

In the present embodiment, the thickness of the n-type semiconductor layer 14 can be optimized by forming the recessed portion 142 in the n-type semiconductor layer 14. According to the present embodiment, efficient depletion can be achieved. In the present embodiment, the sensitivity to received light can be improved by suppressing absorption. The present embodiment can prevent a decrease in element intensity.

In the present embodiment, since the depth D14 of the non-through groove 141 is greater than the depth D11 of the recessed portion 142, effective isolation can be achieved.

The embodiments disclosed in the present application can be modified without departing from the spirit and scope of the invention. The embodiments and variations thereof disclosed in the present application can be combined as appropriate.

Characteristic embodiments have been described to fully and clearly disclose the technique according to the appended claims. However, the appended claims are not to be limited to the embodiments described above and may be configured to embody all variations and alternative configurations that those skilled in the art may make within the fundamental matters set forth herein.

### Variation

In the above description, the p+ type semiconductor layer 13, the n-type semiconductor layer 14, and the n+ type semiconductor layer 15 contain Mg₂Si, but are not limited thereto. In addition to Mg₂Si, crystals having an absorption length shorter than Mg₂Si may be used, such as Mg₂Si-based crystals such as Mg₂Si₁₋ₓSnₓ, Mg₂Sn, and Mg₂Sn-based crystals containing a trace amount of additives, and the like.

Although the non-through groove 141 has been described as having an annular shape, no limitation is intended. The non-through groove 141 may be partially interrupted in the circumferential direction. In the above description, the n+ type semiconductor layer 15 has the cylindrical portion 151 located in the non-through groove 141. However, the n+ type semiconductor layer 15 may not include the cylindrical portion 151. In this case, the material forming the n+ type semiconductor layer 15 and the material forming a cylindrical portion corresponding to the cylindrical portion 151 located in the non-through groove 141 may be different from each other. A layer containing, for example, SiO₂ or MgSiOₓ may be formed on the cylindrical portion. In addition, an air layer may be formed on a cylindrical portion corresponding to the cylindrical portion 151 and located in the non-through groove 141.

### REFERENCE SIGNS

1 Photodiode
11 First electrode
12 Surface protective film
13 p+ type semiconductor layer
13a First surface
13b Second surface
14 n-type semiconductor layer
14b Third surface
14b1 Third portion
15 n+ type semiconductor layer
15al Second portion
15b Fourth surface
15b1 First portion
16 Second electrode
142 Recessed portion

1. A photodiode comprising:
a p+ type semiconductor layer comprising a first surface in contact with a first electrode and a surface protective film located at a peripheral portion of the first electrode;
an n-type semiconductor layer in contact with a second surface of the p+ type semiconductor layer, the second surface opposing the first surface;
an n+ type semiconductor layer in contact with a third surface of the n-type semiconductor layer, the third surface opposing a surface in contact with the second surface; and
a second electrode in contact with a fourth surface of the n+ type semiconductor layer, the fourth surface opposing a surface in contact with the third surface, wherein the p+ type semiconductor layer, the n-type semiconductor layer, and the n+ type semiconductor layer contain Mg₂Si,
the fourth surface of the n+ type semiconductor layer comprises a first portion that is not in contact with the second electrode, and
a recessed portion is provided in a third portion of the third surface of the n-type semiconductor layer, the third portion being in contact with a second portion of the n+ type semiconductor layer, the second portion being a surface opposing the first portion.

2. The photodiode according to claim 1, wherein
the first electrode contains NiAu,
infrared light is incident from a portion of the fourth surface of the n+ type semiconductor layer, the portion being not in contact with the second electrode, and
the infrared light is reflected at a portion of the first electrode, the portion being in contact with the first surface of the p+ type semiconductor layer.

3. The photodiode according to claim 1, wherein
the p+ type semiconductor layer is doped with Ag.

4. The photodiode according to claim 1, wherein
the n+ type semiconductor layer is doped with Al, boron (B), or phosphorus (P).

5. The photodiode according to claim 1, wherein
the fourth surface of the n+ type semiconductor layer comprises a fourth portion in contact with the second electrode, and
a non-through groove is d located in a sixth portion of the third surface of the n-type semiconductor layer, the sixth portion being in contact with a fifth portion of the n+ type semiconductor layer, the fifth portion being a surface opposing the fourth portion.

6. The photodiode according to claim 5, wherein
a depth of the non-through groove is greater than a depth of the recessed portion.

7. A photosensitive device comprising the photodiode described in claim 1.
